(19) United States
(12) Patent Application Publication
(10) Pub. No.: US 2025/0329362 A1
(43) Pub. Date: Oct. 23, 2025

(54) MEMORY DEVICE AND METHOD OF APPLYING PASS VOLTAGE

(71) Applicant: SK hynix Inc., Icheon-si Gyeonggi-do (KR)

(72) Inventor: Eun Woo JO, Icheon-si Gyeonggi-do (KR)

(73) Assignee: SK hynix Inc., Icheon-si Gyeonggi-do (KR)

(21) Appl. No.: 19/033,775

(22) Filed: Jan. 22, 2025

(30) Foreign Application Priority Data
Apr. 18, 2024 (KR) 10-2024-0052115

(51) Int. Cl. G11C 8/08; G11C 5/14; G11C 8/10

(52) U.S. Cl. CPC G11C 8/08; G11C 5/147; G11C 8/10

(57) ABSTRACT

The present technology relates to a memory device. The memory device according to the present technology may include a memory cell array including memory cells, the memory cells connected through a plurality of word lines, a peripheral circuit configured to apply pass voltages to the plurality of word lines and, after applying the pass voltages to the plurality of word lines, configured to apply a program voltage to a select word line, selected among the plurality of word lines, in a period in which a program operation is performed, wherein the pass voltages include a first pass voltage and a second pass voltage, and a control logic configured to control the peripheral circuit so that the second pass voltage is applied to the select word line and the first pass voltage is applied to unselect word lines among the plurality of word lines, which are not selected.

### CROSS-REFERENCE TO RELATED APPLICATION

The present application claims priority under 35 U.S.C. § 119 (a) to Korean patent application number 10-2024-0052115 filed on Apr. 18, 2024, in the Korean Intellectual Property Office, the entire contents of which application is incorporated herein by reference.

### BACKGROUND

### 1. Field of Invention

The present disclosure relates to a memory device, and particularly to a memory device and a method of applying a pass voltage during a program operation.

### 2. Description of Related Art

A memory device is divided into a volatile memory device and a non-volatile memory device. The volatile memory device is a memory device that stores data only when power is supplied and stored data is destroyed when power supply is cut off. The non-volatile memory device is a memory device in which data is not destroyed even though power is cut off.

The memory device may perform a program operation by applying a program voltage through a word line connected to memory cells. The memory device may apply a pass voltage to the word lines before applying the program voltage to a selected word line. As a difference between the program voltage and the pass voltage increases, a time required to increase the program voltage increases and efficiency of the program operation may be reduced.

### SUMMARY

According to an embodiment of the present disclosure, a memory device may include a memory cell array including memory cells, the memory cells connected through a plurality of word lines, a peripheral circuit configured to apply pass voltages to the plurality of word lines and, after applying the pass voltages to the plurality of word lines, configured to apply a program voltage to a select word line, selected among the plurality of word lines, in a period in which a program operation is performed, wherein the pass voltages include a first pass voltage and a second pass voltage, and wherein the second pass voltage is higher than the first pass voltage, and a control logic configured to, during a pass voltage increase period in which the pass voltages are applied, control the peripheral circuit so that the second pass voltage is applied to the select word line and the first pass voltage is applied to unselect word lines, the unselect word lines being word lines, among the plurality of word lines, which are not selected.

According to an embodiment of the present disclosure, a memory device may include a first pass voltage regulator configured to generate a first pass voltage that is applied to unselect word lines, the unselect word lines being word lines that are not selected, among a plurality of word lines connected to memory cells, in a period in which a program operation is performed, a second pass voltage regulator configured to generate a second pass voltage, the second pass voltage being higher than the first pass voltage, which is applied to a select word line, among the plurality of word lines, a program voltage regulator configured to generate a program voltage that is applied to the select word line after applying the second pass voltage to the select word line, switching circuits respectively connecting the first pass voltage regulator, the second pass voltage regulator, and the program voltage regulator with the plurality of word lines, and a control logic configured to control the switching circuits so that the first pass voltage is applied to the unselect word lines and the second pass voltage is applied to the select word line, during a pass voltage increase period in which pass voltages are applied to the plurality of word lines.

According to an embodiment of the present disclosure, a method of operating a memory device may include generating pass voltages applied to a plurality of word lines connected to memory cells while a program operation is performed, wherein the pass voltages include a first pass voltage and a second pass voltage, and wherein the second pass voltage is higher than the first pass voltage, applying a second pass voltage a select word line, selected among the plurality of word lines, during a pass voltage increase period in which the pass voltages are applied to the plurality of word lines, and applying a program voltage to the select word line after the pass voltage increase period.

### BRIEF DESCRIPTION OF THE DRAWINGS

FIG. 1 is a diagram illustrating a memory device according to an embodiment of the present disclosure.

FIG. 2 is a diagram illustrating a connection between voltage regulators and word lines according to an embodiment of the present disclosure.

FIG. 3 is a diagram illustrating a word line voltage changed according to an operation of switches of FIG. 2.

FIG. 4 is a diagram illustrating a voltage of a select word line corresponding to pass voltage application according to an embodiment of the present disclosure.

FIG. 5 is a diagram illustrating a program speed difference between memory cells included in a memory cell array of FIG. 1.

FIG. 6 is a diagram illustrating an increase speed of a program voltage corresponding to pass voltage application according to an embodiment of the present disclosure.

FIG. 7 is a flowchart illustrating a method of applying pass voltages and a program voltage according to an embodiment of the present disclosure.

### DETAILED DESCRIPTION

Specific structural or functional descriptions of embodiments according to the concept which are disclosed in the present specification or application are illustrated only to describe the embodiments according to the concept of the present disclosure. The embodiments according to the concept of the present disclosure may be carried out in various forms and should not be construed as being limited to the embodiments described in the present specification or application.

An embodiment of the present disclosure provides a memory device and a method of applying a pass voltage that improve performance of a program operation by applying an increased pass voltage only to a select word line during a program operation.

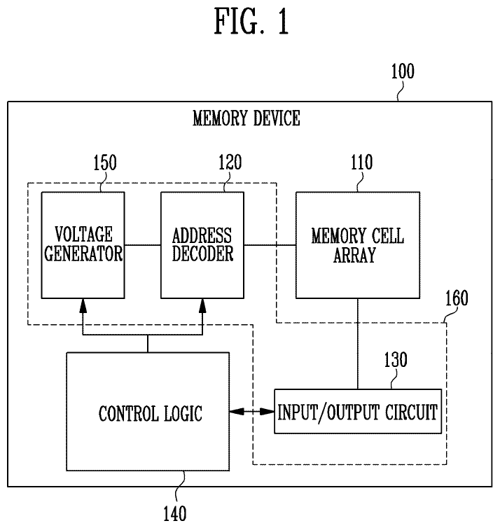

FIG. 1 is a diagram illustrating a memory device according to an embodiment of the present disclosure.

Referring to FIG. 1, the memory device 100 may store data. The memory device 100 may include a memory cell array 110 including memory cells that store data, an address decoder 120 that decodes a column address, an input/output circuit 130 that transmits and receives data to an external device outside of the memory device 100, a control logic 140, and a voltage generator 150 that generates a plurality of voltages having various voltage levels.

Each of the memory cells included in the memory cell array 110 may be a single-level cell (SLC) that stores 1 bit of data or a memory cell that stores multi-bit data. The memory cells that store the multi-bit data may be a multi-level cell (MLC) that store 2 bits of data, a triple-level cells (MLC) that store 3 bits of data, or a quad-level cell (QLC) that stores 4 bits of data according to the number of bits of the multi-bit data.

The address decoder 120 may be connected to the memory cell array 110 through word lines. The address decoder 120 may select a word line by decoding an address received from the input/output circuit 130. The address decoder 120 may apply a voltage received from the voltage generator 150 to a selected word line. The address decoder 120 may operate in response to a control signal received from the control logic 140.

The input/output circuit 130 may include page buffers that read and temporarily store data stored in the memory cells. The input/output circuit 130 may output data stored in the page buffers to an external device outside of the memory device 100 or may store data received from the external device in the page buffer and then store the data in the memory cells.

The control logic 140 may control an overall operation of the memory device 100. The control logic 140 may generate control signals that control the address decoder 120, the input/output circuit 130, and the voltage generator 150 to perform a read operation, a program operation, and an erase operation for the memory cell array 110.

The voltage generator 150 may generate voltages necessary for an operation of the memory device 100. The voltage generator 150 may include voltage regulators that generate voltages having various potentials. The voltage generator 150 may generate a program voltage, a verify voltage, and a read voltage required by the memory device 100. The voltages generated by the voltage generator 150 may be supplied to the memory cells included in the memory cell array 110 through the address decoder 120.

In an embodiment of the present disclosure, the address decoder 120, the input/output circuit 130, and the voltage generator 150 may be referred to as a peripheral circuit 160. The control logic 140 may control the peripheral circuit 160 so that an operation is performed in the memory cells included in the memory cell array 110.

In an embodiment of the present disclosure, the voltage generator 150 may generate pass voltages applied to word lines before the program voltage is applied to select word line. Potentials of the pass voltages generated by the voltage regulators included in the voltage generator 150 may be different from each other.

The address decoder 120 may include switching circuits that respectively connect the voltage regulators included in the voltage generator 150 with the word lines. Through a switching operation, a select word line and unselect word lines may be connected to different voltage regulators.

The control logic 140 may control the peripheral circuit 160 so that the pass voltages are applied to the word lines before applying the program voltage to the select word line that is selected among the word lines. A period in which the pass voltages are applied may be referred to as a pass voltage increase period. The control logic 140 may control the peripheral circuit 160 so that a pass voltage that is higher than the pass voltage applied to the unselect word line is applied to the select word line during the pass voltage increase period.

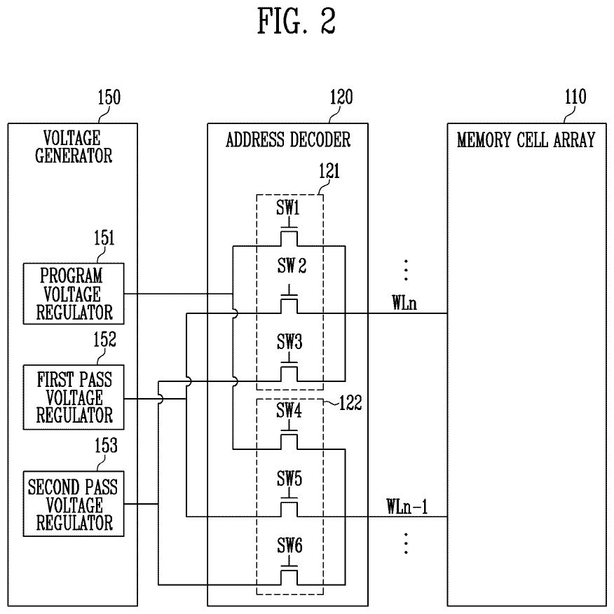

FIG. 2 is a diagram illustrating a connection between voltage regulators and word lines according to an embodiment of the present disclosure.

Referring to FIG. 2, the memory cell array 110 may be connected to the address decoder 120 through a plurality of word lines. The address decoder 120 may receive voltages from the voltage generator 150 and may transmit, through the plurality of word lines, the received voltages to the memory cells of the memory cell array 110.

For convenience of description, it may be assumed that the select word line that is selected among the plurality of word lines is an N-th word line WLn. An (N-1)-th word line WLn-1, shown in FIG. 2, may represent the unselect word lines, unselect word lines being the word lines that are not selected, among the plurality of word lines.

The address decoder 120 may include switching circuits that respectively connect the voltage regulators included in the voltage generator 150 with the word lines. In FIG. 2, a first switching circuit 121 connected to the select word line and a second switching circuit 122 connected to the unselect word line are shown as an example. The first switching circuit 121 may include a first switch SW1, a second switch SW2, and a third switch SW3. Similarly, the second switch circuit 122 may include a fourth switch SW4, a fifth switch SW5, and a sixth switch SW6. The address decoder 120 may change the status (turn-on/turn-off) of the first switch SW1, the second switch SW2, the third switch SW3, the fourth switch SW4, the fifth switch SW5, and the sixth switch SW6 based on the control signal received from the control logic 140.

The voltage generator 150 may include a program voltage regulator 151, a first pass voltage regulator 152, and a second pass voltage regulator 153. The program voltage regulator 151 may generate the program voltage applied to the select word line. The first pass voltage regulator 152 may generate a first pass voltage applied to the unselect word lines. The second pass voltage regulator 153 may generate a second pass voltage, the second pass voltage being higher than the first pass voltage. In an embodiment of the present disclosure, the second pass voltage may be applied to the select word line before the program voltage is applied to the select word line.

The first switching circuit 121 may select one of the program voltage regulator 151, the first pass voltage regulator 152, and the second pass voltage regulator 153 and may connect the selected regulator to the select word line. For example, when the first switch SW1 is turned on, the second switch SW2 and the third switch SW3 may be turned off, resulting in the program voltage regulator 151 and the select word line being connected. In this case, the program voltage generated by the program voltage regulator 151 may be applied to the select word line. Similarly, when only the third switch SW3 is turned on, the second pass voltage may be applied to the select word line. When the select word line and the first switching circuit 121 are connected, the second switch SW2 may be maintained at a turn-off state.

The second switching circuit 122 may select one of the program voltage regulator 151, the first pass voltage regulator 152, and the second pass voltage regulator 153 and may connect the selected regulator to the select word line. When the unselect word line and the second switching circuit 122 are connected, the fourth switch SW4 and the sixth switch SW6 may be maintained at a turn-off state, and only the fifth switch SW5 may be turned on.

The structure of the first switching circuit 121 and the second switching circuit 122, shown in FIG. 2, is merely an example, and the structure of the switching circuit may vary. When the select word line to which the program voltage is applied is changed from the N-th word line WLn to another word line, the first switching circuit 121 and the second switching circuit 122 may select another voltage regulator and may connect the selected voltage regulator to the word line.

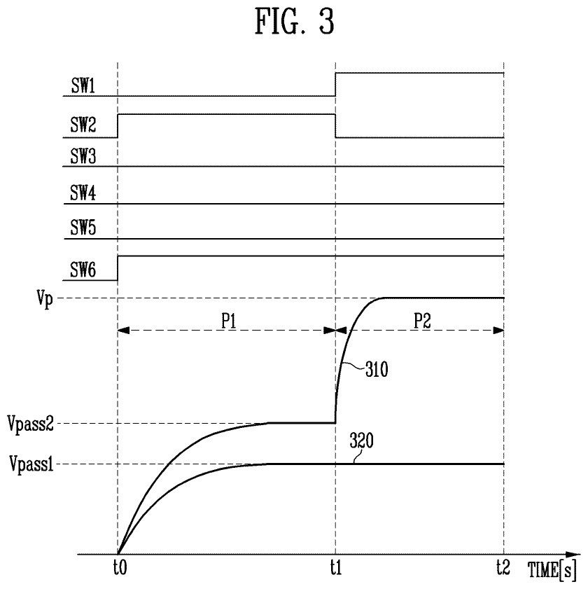

FIG. 3 is a diagram illustrating a word line voltage changed according to an operation of the switches of FIG. 2.

Referring to FIG. 3, a voltage 310 of the select word line and a voltage 320 of the unselect word line is illustrated according to an operation of the first switch SW1, the second switch SW2, the third switch SW3, the fourth switch SW4, the fifth switch SW5, and the sixth switch SW6. The pass voltage may be applied to the word lines from a time point t0, and the program voltage may be applied to the select word line from a time point t1.

A pass voltage increase period P1 in which the pass voltages are applied to the word lines may be a period between to and t1, and a program voltage application period P2 may be a period between t1 and t2. At t0, the second switch SW2 and the sixth switch SW6 may be turned on, and the first switch SW1, the third switch SW3, the fourth switch SW4, and the fifth switch SW5 may be maintained at a turn-off state. During the pass voltage increase period P1, a first pass voltage Vpass1 may be applied to the unselect word lines, and a second pass voltage Vpass2 may be applied to the select word lines. During the pass voltage increase period P1, the select word line voltage 310 may reach a second pass voltage Vpass2, and the unselect word line voltage 320 may reach a first pass voltage Vpass1.

At t1, the first switch SW1 may be turned on, and the second switch SW2 may be turned off. The third switch SW3, the fourth switch SW4, and the fifth switch SW5 may be maintained at a turn-off state, and the sixth switch SW6 may be maintained at a turn-on state. During the program voltage application period P2, the program voltage Vp may be applied to the select word lines, and the first pass voltage Vpass1 may be maintained in the unselect word lines. The program voltage application period P2 may include an increase period of the select word line voltage 310. The select word line voltage 310 may reach the program voltage Vp.

In an embodiment of the present disclosure, during the pass voltage increase period P1, before the program voltage Vp is applied to the select word line, the second pass voltage Vpass2 that is higher than the first pass voltage Vpass1 may be applied to the select word line. Since the voltage 310 of the select word line increases to the second pass voltage Vpass2 due to the application of the second pass voltage Vpass2, a time in which the voltage 310 of the select word line increases to the program voltage Vp in the program voltage application period P2 may be reduced.

In an embodiment of the present disclosure, the control logic may generate a first control signal for applying the pass voltage to the corresponding word lines during the pass voltage increase period P1. In response to the first control signal, the second switch SW2 and the sixth switch SW6 may be turned on, and the remaining switches SW1, SW3, SW4, and SW5 may be maintained at a turn-off state. The select word line may be connected to the second pass voltage regulator 153, and the unselect word lines may be connected to the first pass voltage regulator 152.

The control logic may generate a second control signal for applying the program voltage Vp to the select word line during the program voltage application period P2 after the pass voltage increase period P1. In response to the second control signal, the first switch SW1 may be turned on, the second switch SW2 may be turned off, the third switch SW3, the fourth switch SW4, and the fifth switch SW5 may be maintained at a turn-off state, and the sixth switch SW6 may be maintained at a turn-on state. The program voltage regulator 151 may be connected to the select word line, and a connection of the second pass voltage regulator 153, which is connected during the pass voltage increase period P1, may be released. A connection between the unselect word lines and the first pass voltage regulator 152 may be maintained.

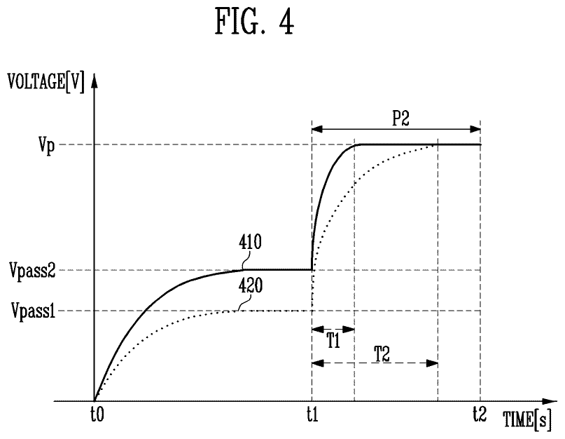

FIG. 4 is a diagram illustrating a voltage of a select word line corresponding to pass voltage application according to an embodiment of the present disclosure.

Referring to FIG. 4, a comparison between a voltage 410 and a voltage 420 of the select word line is illustrated. Specifically, according to an embodiment of the present disclosure, the voltage 410 may represent the change in voltage of the select word line when the initial pass voltage is the second pass voltage Vpass2 while the voltage 420 may represent the change in voltage of the select word line when the initial pass voltage is the first pass voltage Vpass1. In a description of FIG. 4, portions corresponding to the description of FIG. 3 may be omitted.

At t1, the voltage 410 of the select word line may be higher than the voltage 420 of the select word line during the pass voltage increase period which corresponds to P1 of FIG. 3. In an embodiment of the present disclosure, 410 may be different from 420 by up to 5V.

When the program voltage Vp is applied at t1, a time in which the select word line voltage reaches the program voltage Vp may be different for 410 and 420 due to the different starting voltage levels of Vpass1 and Vpass2. In FIG. 4, a first period T1 may represent a time required for the voltage 410 of the select word line to reach the program voltage Vp, and the second period T2 may represent a time required for the voltage 420 of the select word line to reach the program voltage Vp. The first period T1 and the second period T2 may represent an increase period in which the voltage of the select word line increases after the program voltage Vp is applied.

In FIG. 4, since a difference between the program voltage Vp and 410 at t1 is less than a difference between the program voltage Vp and 420 at t1, the first period T1 may be shorter than the second period T2. According to an embodiment of the present disclosure, since the voltage increase period of the select word line is shorter for 420, the required time for programming may be shorter than the time required when the first pass voltage Vpass1 is applied to the select word line. Efficiency of the program operation may be improved by applying the second pass voltage Vpass2 before applying the program voltage Vp.

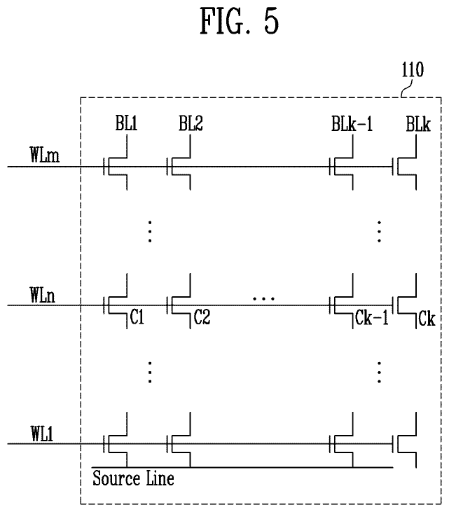

FIG. 5 is a diagram illustrating a program speed difference of the memory cells included in the memory cell array of FIG. 1.

Referring to FIG. 5, the memory cell array 110 and the memory cells connected through word lines are illustrated. It may be assumed that M word lines are connected to the memory cells, and the number of memory cells connected to one word line is k.

The memory cells may be connected in series between a bit line and a source line. A gate of a plurality of memory cells may be connected to one word line. For convenience of description, it may be assumed that an N-th word line WLn, among M word lines, is the select word line. In FIG. 5, memory cells C1 to Ck connected to the select word line are illustrated.

A program speed of each of the memory cells C1 to Ck connected to the select word line may vary according to a distance from the address decoder 120. The program speed may be related to a potential increase speed of the word line voltage applied to the memory cell. It may be assumed that the first memory cell C1 is closest to the address decoder 120 and the k-th memory cell Ck is the farthest from the address decoder 120, among the memory cells C1 to Ck connected to the select word line. Among the memory cells C1 to Ck connected to the select word line, the program speed or the potential increase speed of the word line voltage of the first memory cell C1 may be the fastest, and the program speed or the potential increase speed of the word line voltage of the k-th memory cell Ck may be the slowest.

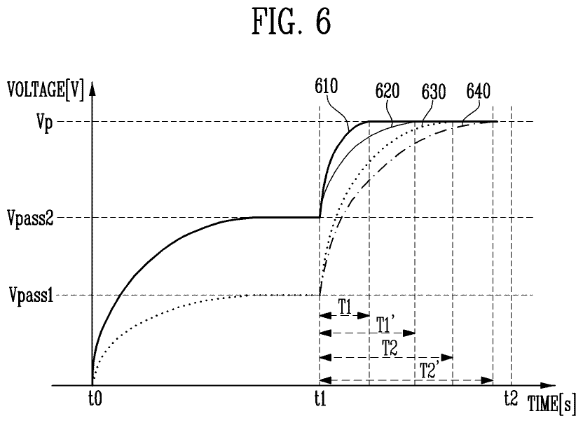

FIG. 6 is a diagram illustrating an increase speed of a program voltage corresponding to pass voltage application according to an embodiment of the present disclosure.

Referring to FIG. 6, select word line voltages are illustrated according to the pass voltage applied before the program voltage Vp is applied and a position of the memory cell on the select word line. In the description of FIG. 6, a part corresponding to the description of FIGS. 3 and 4 may be omitted.

In conjunction with FIG. 5, when the program voltage Vp is applied to the select word line after applying the second pass voltage Vpass2 to the select word line, 610 may represent the select word line voltage of the first memory cell C1 having the shortest distance from the address decoder 120, among the select word lines. T1 may represent an increase period of the select word line voltage of the first memory cell C1 to which the second pass voltage Vpass2 is applied. 620 may represent the select word line voltage of the k-th memory cell Ck having the farthest distance from the address decoder 120, among the select word lines. T1′ may represent an increase period of the select word line voltage of the k-th memory cell Ck to which the second pass voltage Vpass2 is applied. Due to the position of the first memory cell C1 and the k-th memory cell Ck, T1′ may be longer than T1.

630 may represent the select word line voltage of the first memory cell C1 having the shortest distance from the address decoder 120, among the select word lines, when the program voltage Vp is applied to the select word line after applying the first pass voltage Vpass1 to the select word line. T2 may represent an increase period of the select word line voltage of the first memory cell C1 to which the first pass voltage Vpass1 is applied. 640 may represent the select word line voltage of the k-th memory cell Ck having the farthest distance from the address decoder 120 among the select word lines, when the program voltage Vp is applied to the select word line after applying the first pass voltage Vpass1 to the select word line. T2′ may represent an increase period of the select word line voltage of the k-th memory cell Ck to which the first pass voltage Vpass1 is applied. Due to the position of the first memory cell C1 and the k-th memory cell Ck, T2′ is longer than T2.

In an embodiment of the present disclosure, the first pass voltage Vpass1 may be 5V or less, and the second pass voltage Vpass2 may be 10V or less. When the second pass voltage Vpass2 is applied to the select word line before applying the program voltage Vp, the voltage increase period of the select word line may be decreased. As the voltage increase period of the select word line is decreased, an influence of a program speed difference based on the different positions of the memory cells in the select word line may be decreased. That is, efficiency of the program operation may be increased and the number of verify operations may be decreased.

On the other hand, when the first pass voltage Vpass1 is identically applied to all word lines before applying the program voltage Vp, the voltage increase period of the select word line may be increased. As the voltage increase period is increased, an influence of the program speed difference according to the position of the memory cells in the select word line may be increased.

In addition, when the second pass voltage Vpass2 is identically applied to all word lines before applying the program voltage Vp, the program speed of the select word line may be increased, but the voltage of the unselect word lines may be increased. Pass disturbance and a current may be increased due to the voltage increase of the unselect word lines. Power consumption may be increased due to the current increase.

In an embodiment of the present disclosure, the voltage increase period of the select word line may be decreased by only increasing a size of the pass voltage applied to the select word line. The memory device may include a separate pass voltage regulator that generates the pass voltage applied to the select word line before the program voltage is applied. An influence on the program speed due to the position of the memory cells connected to the select word line may be decreased by the decrease of the voltage increase period. Since only the pass voltage applied to the select word line is increased, disturbance and a current increase due to the pass voltage may be minimized. Power consumption may also be decreased by minimizing the current increase.

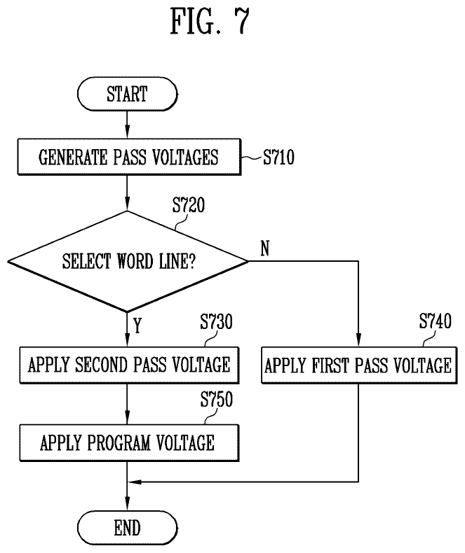

FIG. 7 is a flowchart illustrating a method of applying pass voltages and a program voltage according to an embodiment of the present disclosure.

Referring to FIG. 7, while performing the program operation, the memory device may apply the program voltage to the select word line selected among the plurality of word lines and may apply the pass voltage to remaining unselect word lines. Before the program voltage is applied to the select word line, the pass voltage may be applied similarly to the unselect word lines. The memory device may increase the voltage of the select word line by applying a pass voltage that is higher than the pass voltage applied to the unselect word line to the select word line to which the program voltage is to be applied. Efficiency of the program operation may be increased by the increased voltage of the select word line.

In step S710, the memory device may generate the pass voltages to be applied to the plurality of word lines to which the memory cells are connected. The first pass voltage regulator may generate the first pass voltage applied to the unselect word lines that are not selected, among the plurality of word lines. The second pass voltage regulator may generate the second pass voltage that is higher than the first pass voltage.

In step S720, the memory device may distinguish between the select word line and the unselect word lines, among the plurality of word lines. In the case of the select word line, step S730 may be performed, and in the case of the unselect word lines, step S740 may be performed.

In step S730, the address decoder may apply the second pass voltage to the select word line. The second pass voltage may be applied to the select word line during the pass voltage increase period. The switching circuits included in the address decoder may connect the second pass voltage regulator with the select word line.

In step S740, the address decoder may apply the first pass voltage to the unselect word lines. The switching circuits included in the address decoder may connect the first pass voltage regulator with the unselect word lines. The first pass voltage may be applied to the unselect word lines even during the period in which the program voltage is applied to the select word line after the pass voltage increase period. The connection of the first pass voltage regulator and the unselect word lines may be maintained.

In step S750, the program voltage may be applied to the select word line. The control logic may generate the control signal for applying the program voltage to the select word line. The program voltage regulator may generate the program voltage, and switching circuits may release the connection between the second pass voltage regulator and the select word line and may connect the program voltage regulator with the select word line.

Each of steps of FIG. 7 may correspond to the description of FIGS. 2 to 6.

What is claimed is:

1. A memory device comprising:
a memory cell array including memory cells, the memory cells connected through a plurality of word lines;
a peripheral circuit configured to apply pass voltages to the plurality of word lines and, after applying the pass voltages to the plurality of word lines, configured to apply a program voltage to a select word line, selected among the plurality of word lines, in a period in which a program operation is performed, wherein the pass voltages include a first pass voltage and a second pass voltage, and wherein the second pass voltage is higher than the first pass voltage; and
a control logic configured to, during a pass voltage increase period in which the pass voltages are applied, control the peripheral circuit so that the second pass voltage is applied to the select word line and the first pass voltage is applied to unselect word lines, the unselect word lines being word lines, among the plurality of word lines, which are not selected.

2. The memory device of claim 1, wherein the peripheral circuit comprises:
a voltage generator including a first pass voltage regulator generating the first pass voltage and a second pass voltage regulator generating the second pass voltage; and
an address decoder connecting a plurality of voltage regulators included in the voltage generator with the plurality of word lines.

3. The memory device of claim 2, wherein the control logic generates a first control signal for applying the pass voltages to the corresponding word lines, among the plurality of word lines, during the pass voltage increase period, and
wherein the address decoder connects the first pass voltage regulator with the unselect word lines and connects the second pass voltage regulator with the select word line in response to the first control signal.

4. The memory device of claim 2, wherein the voltage generator further includes a program voltage regulator generating the program voltage, and
wherein the control logic generates a second control signal for applying the program voltage to the select word line after the pass voltage increase period.

5. The memory device of claim 4, wherein the address decoder connects the select word line with the program voltage regulator in response to the second control signal.

6. The memory device of claim 5, wherein the address decoder maintains a connection between the first pass voltage regulator and the unselect word lines and releases a connection between the second pass voltage regulator and the select word line.

7. The memory device of claim 2, wherein the address decoder includes switching circuits connecting the plurality of voltage regulators with the plurality of word lines, respectively.

8. The memory device of claim 7, wherein the switching circuits connects each of the plurality of word lines with one voltage regulator, among the plurality of voltage regulators.

9. A memory device comprising:
a first pass voltage regulator configured to generate a first pass voltage that is applied to unselect word lines, the unselect word lines being word lines that are not selected, among a plurality of word lines connected to memory cells, in a period in which a program operation is performed;
a second pass voltage regulator configured to generate a second pass voltage, the second pass voltage being higher than the first pass voltage, which is applied to a select word line, among the plurality of word lines;
a program voltage regulator configured to generate a program voltage that is applied to the select word line after applying the second pass voltage to the select word line;
switching circuits respectively connecting the first pass voltage regulator, the second pass voltage regulator, and the program voltage regulator with the plurality of word lines; and
a control logic configured to control the switching circuits so that the first pass voltage is applied to the unselect word lines and the second pass voltage is applied to the select word line, during a pass voltage increase period in which pass voltages are applied to the plurality of word lines.

10. The memory device of claim 9, wherein the control logic generates a first control signal for applying the first and second pass voltages to the corresponding word lines, among the plurality of word lines, during the pass voltage increase period.

11. The memory device of claim 10, wherein the switching circuits connect the first pass voltage regulator with the unselect word lines and connect the second pass voltage regulator with the select word line in response to the first control signal.

12. The memory device of claim 10, wherein the control logic generates a second control signal for applying the program voltage to the select word line after the pass voltage increase period.

13. The memory device of claim 12, wherein the switching circuits connect the program voltage regulator with the select word line in response to the second control signal.

14. The memory device of claim 13, wherein the switching circuits maintain a connection between the first pass voltage regulator and the unselect word lines and releases a connection between the second pass voltage regulator and the select word line.

15. A method of operating a memory device, the method comprising:
generating pass voltages applied to a plurality of word lines connected to memory cells while a program operation is performed, wherein the pass voltages include a first pass voltage and a second pass voltage, and wherein the second pass voltage is higher than the first pass voltage;
applying a second pass voltage a select word line, selected among the plurality of word lines, during a pass voltage increase period in which the pass voltages are applied to the plurality of word lines; and
applying a program voltage to the select word line after the pass voltage increase period.

16. The method of claim 15, wherein generating the pass voltages comprises:
generating the first pass voltage by a first pass voltage regulator; and
generating the second pass voltage by a second pass voltage regulator.

17. The method of claim 16, wherein applying the second pass voltage further comprises applying the first pass voltage to unselect word lines, the unselect word lines being word lines, among the plurality of word lines, which are not selected during the pass voltage increase period.

18. The method of claim 17, wherein applying the program voltage further comprises releasing a connection between the second pass voltage regulator and the select word line.
